(19) United States
(12) Patent Application Publication
(10) Pub. No.: US 2025/0280663 A1
(43) Pub. Date: Sep. 4, 2025

(54) Display Device

(71) Applicant: LG Display Co., Ltd., Seoul (KR)

(72) Inventors: Jung Seop Yoon, Paju-si (KR); Byung June Mun, Paju-si (KR)

(21) Appl. No.: 19/010,816

(22) Filed: Jan. 6, 2025

(30) Foreign Application Priority Data
Feb. 29, 2024 (KR) 10-2024-0030267

(51) Int. Cl. H10K 59/122; H10K 59/35; H10K 59/40; H10K 59/80

(52) U.S. Cl. CPC H10K 59/122; H10K 59/353; H10K 59/40; H10K 59/80515; H10K 59/873

(57) ABSTRACT

Provided is a display device. A substrate includes a subpixel including a plurality of emission areas. A first insulating layer is disposed over the substrate. A second insulating layer is disposed over the first insulating layer, and includes a recess in the subpixel. A protruding pattern is disposed within the recess. A first electrode is disposed over the second insulating layer, and overlaps the recess and the protruding pattern. A bank is disposed over a top surface of the first electrode and the second insulating layer, and includes an open area in the subpixel. An emission layer is disposed over the first electrode. A second electrode is disposed over the emission layer.

### CROSS REFERENCE TO RELATED APPLICATION

This application claims priority from Republic of Korea Patent Application No. 10-2024-0030267, filed on Feb. 29, 2024, which is hereby incorporated by reference in its entirety.

### BACKGROUND

### Field

Embodiments of the present disclosure relate to a display device.

### Description of Related Art

Along with the development of the information society, demand for various types of image displaying devices is increasing. Recently, a range of display devices, such as liquid crystal display (LCD) devices, plasma display devices, and light-emitting diode (LED) display devices, have recently come into widespread use.

Such a display device emits light to the outside of the display device to display images. It is difficult to improve the brightness of the display device due to problems such as light being trapped inside the display device instead of being emitted to the outside of the display device.

The display device may also be required to maintain excellent brightness as the viewing angle from which the user views the screen changes.

### SUMMARY

Embodiments of the present disclosure may provide a display device capable to improve light extraction efficiency.

Embodiments of the present disclosure may provide a display device capable to improve brightness in the direction of a side viewing angle.

Embodiments of the present disclosure may provide a display device capable to operate at low power consumption by improving light extraction efficiency and brightness in the direction of a side viewing angle.

According to embodiments of the present disclosure, a display device includes: a substrate including a subpixel including a plurality of emission areas; a first insulating layer disposed over the substrate; a second insulating layer disposed over the first insulating layer, and including a recess in the subpixel; a protruding pattern disposed within the recess; a first electrode disposed over the second insulating layer, and overlapping the recess and the protruding pattern; a bank disposed over a top surface of the first electrode and the second insulating layer, and including an open area in the subpixel; an emission layer disposed over the first electrode; and a second electrode disposed over the emission layer.

According to embodiments of the present disclosure, a display device includes: a substrate including a subpixel disposed in an active area; a first emission area located in the subpixel; a third emission area located in the subpixel and surrounding the first emission area; a second emission area located in the subpixel and surrounding the third emission area; a second non-emission area located in the subpixel and surrounding the second emission area; and a fourth emission area located in the subpixel and surrounding the second non-emission area, wherein a recess is disposed in the subpixel, and a protruding pattern is disposed within the recess.

According to embodiments of the present disclosure, the display device may include the protruding pattern in the subpixel to improve light extraction efficiency.

According to embodiments of the present disclosure, the display device may include the protruding pattern to improve brightness in the direction of a side viewing angle.

According to embodiments of the present disclosure, the display device may operate at low power consumption due to improved light extraction efficiency and improved brightness in the direction of a side viewing angle.

### BRIEF DESCRIPTION OF DRAWINGS

The above and other objectives, features, and advantages of the present disclosure will be more clearly understood from the following detailed description, taken in conjunction with the accompanying drawings, in which:

FIG. 1 illustrates a system configuration of a display device according to embodiments;

FIG. 2 illustrates a display panel according to embodiments of the present disclosure;

FIGS. 3 to 5 are example plan views illustrating subpixels arranged in an active area in the display device according to embodiments of the present disclosure;

FIG. 6 is an example cross-sectional view taken along A-A′ line of FIG. 3 according to embodiments of the present disclosure;

FIG. 7 is an example cross-sectional view illustrating the protruding pattern shown in FIG. 6 according to embodiments of the present disclosure; and

FIGS. 8 to 10 are other example cross-sectional views taken along A-A′ line of FIG. 3 according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting”, “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, a variety of embodiments will be described in detail with reference to the accompanying drawings.

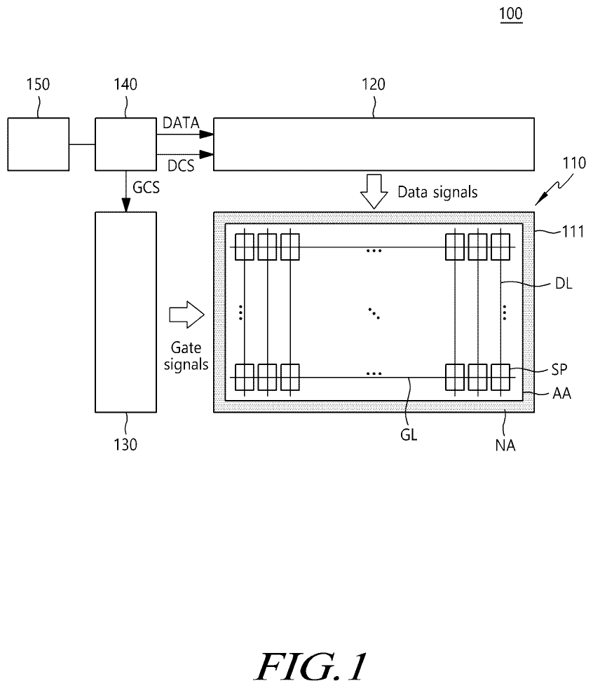

FIG. 1 illustrates a system configuration of a display device 100 according to embodiments.

Referring to FIG. 1, the display device 100 according to embodiments may include a display panel 110 and display driver circuits as image displaying components. The display driver circuits are circuits for driving the display panel 110, and may include a data driver circuit 120, a gate driver circuit 130, a controller 140, and the like.

The display panel 110 may include a substrate 111 and a plurality of subpixels SP disposed on the substrate 111.

The substrate 111 may include an active area AA capable of displaying an image and a non-active area NA located outside the active area AA.

The active area AA may include a plurality of subpixels SP for displaying an image. The non-active area NA may include a pad area located in a first direction (e.g., a column direction or a row direction) from the active area AA.

In display panel 110 according to embodiments, the non-active area NA may be significantly limited. In the present disclosure, the non-active area NA is also referred to as a “bezel”. For example, the non-active area NA may include a first non-active area that is located outside the active area AA in a first direction, a second non-active area that is located outside the active area AA in a second direction, a third non-active area that is located outside the active area AA in the first direction, and a fourth non-active area that is located outside the active area AA in the second direction. The first non-active area of the first to fourth non-active areas may include a pad area to which the driver circuit is connected or bonded. The second to fourth non-active areas of the first to fourth non-active areas that do not include a pad area may have a very limited size.

In another example, a boundary area between the active area AA and the non-active area NA may be bent such that the non-active area NA is located below the active area AA. In this case, when a user looks at the display device 100 from the front, there may be little or no non-active area NA visible to the user.

On the substrate 111 of the display panel 110, various types of signal lines for driving the plurality of subpixels SP may be disposed.

The display device 100 according to embodiments may be a liquid crystal display device or the like or may be a self-luminous display device in which the display panel 110 emits light by itself. When the display device 100 according to embodiments is a self-luminous display device, each of the plurality of subpixels SP may include a light emitting element.

For example, the display device 100 according to embodiments may be an organic light emitting display device in which the light emitting element is implemented as an organic light-emitting diode (OLED). In another example, the display device 100 according to embodiments may be an inorganic light emitting display device in which the light emitting element is implemented as a light-emitting diode based on an inorganic material. In another example, the display device 100 according to embodiments may be a quantum dot display device in which the light emitting element is implemented as a quantum dot that is a semiconductor crystal emitting light by itself.

Depending on the type of the display device 100, each of the plurality of subpixels SPs may have different structures. For example, when the display device 100 is a self-luminous display device in which the subpixels SP emit light by themselves, each subpixel SP may include a self-luminous emitting element, one or more transistors, and one or more capacitors.

For example, the various types of signal lines may include a plurality of data lines DL carrying data signals (also referred to as data voltages or image signals) and a plurality of gate lines GL carrying gate signals (also referred to as scan signals).

For example, the plurality of data lines DL may intersect the plurality of gate lines GL. Each of the plurality of data lines DL may be disposed extending in a first direction, and each of the plurality of gate lines GL may be disposed extending in a second direction. Here, the first direction may be a column direction and the second direction may be a row direction. In another example, the first direction may be a row direction and the second direction may be a column direction. In the following, for the sake of brevity, each of the plurality of data lines DL will be illustrated as being disposed in the column direction and each of the plurality of gate lines GL will be illustrated as being disposed in the row direction.

The data driver circuit 120 may be a circuit for driving the plurality of data lines DL and may output data signals to the plurality of data lines DL.

The data driver circuit 120 may receive digital image data DATA from the controller 140, convert the received image data DATA to an analogue data signal, and output the analogue data signal to the plurality of data lines DL.

For example, the data driver circuit 120 may be coupled to the display panel 110 by a tape-automated bonding (TAB) method, may be coupled to bonding pads on the display panel 110 by a chip-on-glass (COG) or chip-on-panel (COP) method, or may be implemented by a chip-on-film (COF) method and coupled to the display panel 110, but is not limited thereto.

The data driver circuit 120 may be connected to a first side (e.g., the top or bottom side) of the display panel 110. In another example, data driver circuit 120 may be connected to the opposite sides (e.g., both the top and bottom sides) of the display panel 110 or to two or more of the four sides of display panel 110, depending on the driving method, the panel design, and the like.

The data driver circuit 120 may be connected to a portion outside the active area AA of the display panel 110, but in another example, may be disposed within the active area AA of the display panel 110.

The gate driver circuit 130 may be a circuit for driving the plurality of gate lines GL, and may output gate signals to the plurality of gate lines GL.

The gate driver circuit 130 may be supplied with a first gate voltage corresponding to a turn-on level voltage and a second gate voltage corresponding to a turn-off level voltage along with various gate drive control signals GCS to generate gate signals, and may supply the generated gate signals to the plurality of gate lines GL.

In the display device 100 according to embodiments, the gate driver circuit 130 may be embedded in the display panel 110 by a gate-in-panel (GIP) method. When the gate driver circuit 130 is a gate-in-panel circuit, the gate driver circuit 130 may be provided over the substrate 111 of the display panel 110 during the fabrication process of the display panel 110.

For example, the gate driver circuit 130 may be disposed in the non-active area NA of the display panel 110.

In another example, the gate driver circuit 130 may be disposed in the active area AA of the display panel 110. In this case, in an example, the gate driver circuit 130 may be disposed in a first portion of the active area AA (e.g., a left portion or a right portion of the active area AA). In another example, the gate driver circuit 130 may be disposed in a first portion of the active area AA (e.g., a left portion or a right portion of the active area AA) and a second portion of the active area AA (e.g., a right portion or a left portion of the active area AA).

In the present disclosure, the gate driver circuit 130 embedded in the display panel 110 by the gate-in-panel (GIP) method may also be referred to as the “gate-in-panel circuit”.

The controller 140 is a device controlling the data driver circuit 120 and the gate driver circuit 130, and may control the drive timing for the plurality of data lines DL and the drive timing for the plurality of gate lines GL.

The controller 140 may supply a data drive control signal DCS to the data driver circuit 120 to control the data driver circuit 120 and a gate drive control signal GCS to the gate driver circuit 130 to control the gate driver circuit 130.

The controller 140 may receive input video data from a host system 150 and supply video data to the data driver circuit 120 based on the input video data.

The controller 140 may be implemented as a separate component from the data driver circuit 120 or may be integrated with the data driver circuit 120 to form an integrated circuit.

The controller 140 may be a timing controller used in typical display technology, may be a controller including a timing controller and performing other control functions, may be a controller other than the timing controller, or may be a circuit of a controller. The controller 140 may be implemented as a variety of circuits or electronic components, such as an integrated circuit (IC), a field programmable gate array (FPGA), an application specific integrated circuit (ASIC), or a processor, but is not limited thereto.

The controller 140 may be mounted on a printed circuit board (PCB), a flexible printed circuit (FPC), or the like, and may be electrically connected to the data driver circuit 120 and the gate driver circuit 130 through the PCB, the FPC, or the like.

The controller 140 may transmit and receive signals to and from the data driver circuit 120 using one or more predetermined interfaces. For example, the interfaces may include, but are not limited to, a low voltage differential signaling (LVDS) interface, an embedded clock point to point interface (EPI), a serial peripheral interface (SPI), and the like.

To further provide a touch sensing function in addition to an image displaying function, the display device 100 according to embodiments may include a touch sensor and a touch sensing circuit for detecting whether a touch is caused by a touch object, such as a finger or a pen (e.g., a stylus), or for determining a touch position by sensing the touch sensor.

The touch sensing circuit may include a touch driver circuit to drive and sense the touch sensor to generate and output touch sensing data and a touch controller to detect a touch occurrence or determine a touch position using the touch sensing data.

The touch sensor may include a plurality of touch electrodes. The touch sensor may further include a plurality of touch lines for electrically coupling the plurality of touch electrodes to the touch driver circuit.

The touch sensor may be present either outside the display panel 110 in the form of a touch panel or inside the display panel 110. When the touch sensor is in the form of a touch panel external to the display panel 110, the touch sensor is referred to as an add-on touch sensor. When the touch sensor is an add-on touch sensor, the touch panel and the display panel 110 may be fabricated separately and fitted together during assembly. Such an add-on touch panel may include a substrate for the touch panel and a plurality of touch electrodes on the substrate for the touch panel.

When the touch sensor is present inside the display panel 110, the touch sensor may be provided on the substrate during the fabrication process of the display panel 110, along with signal lines and electrodes associated with display driving.

The touch driver circuit may supply a touch driving signal to at least one of the touch electrodes, and may sense at least one of the touch electrodes to generate touch sensing data.

The touch sensing circuit may perform touch sensing by self-capacitance sensing or mutual-capacitance sensing.

When the touch circuit performs touch sensing by the self-capacitance sensing, the touch circuit may perform touch sensing based on the capacitance between each touch electrode and a touch object (e.g., a finger or a pen (e.g., a stylus)). According to the self-capacitance sensing, each of the touch electrodes may act as both a driving touch electrode and a sensing touch electrode. The touch driver circuit may drive all or some of the touch electrodes and sense all or some of the touch electrodes.

When the touch circuit performs touch sensing by the mutual capacitance sensing, the touch circuit may perform touch sensing based on the capacitance between the touch electrodes. According to the mutual capacitance sensing, the touch electrodes are divided into driving touch electrodes and sensing touch electrodes. The touch driver circuit may drive the driving touch electrodes and sense the sensing touch electrodes.

The touch driver circuit and the touch controller of the touch sensing circuit may be implemented as separate devices or as a single device. The touch driver circuit and the data driver circuit may also be implemented as separate devices or as a single device.

The display device 100 may further include, for example, a power supply circuit for supplying various power to the display driver circuit and/or the touch sensing circuit.

The display device 100 according to embodiments may be, but is not limited to, a mobile device, such as a smartphone or a tablet, or a monitor of various sizes, a television set (TV), or the like, and may be any display of various types and various sizes capable of displaying information or images (or videos).

The display device 100 according to embodiments may further include electronic devices such as a camera (or an image sensor) and a detection sensor. For example, a detection sensor may be a sensor that receives light, such as infrared, ultrasonic, or ultraviolet light, to detect an object or a human body.

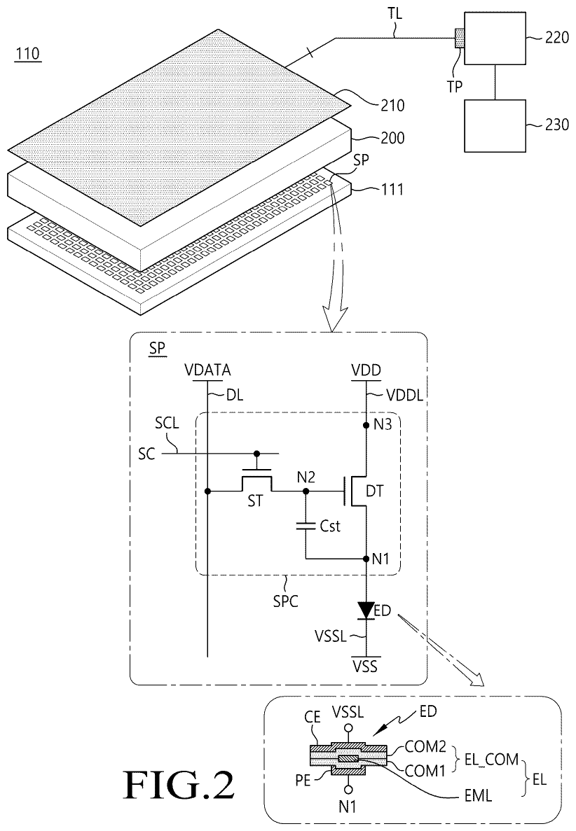

FIG. 2 illustrates a display panel 110 according to embodiments of the present disclosure.

Referring to FIG. 2, the display panel 110 may include a substrate 111 on which a plurality of subpixels SP are disposed and an encapsulation layer 200 over the substrate 111. The encapsulation layer 200 may also be referred to as an encapsulation substrate, an encapsulation part, or the like.

Referring to FIG. 2, when the display device 100 according to embodiments is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors for driving the light emitting element ED and at least one capacitor. In the present disclosure, the subpixel circuit SPC may drive the light emitting element ED by supplying a driving current to the light emitting element ED at predetermined timing. The light emitting element ED may be driven by the driving current to emit light.

The plurality of transistors may include a driving transistor DT to drive the light emitting element ED and a scanning transistor ST to be turned on or turned off based on a scanning signal SC. The driving transistor DT may supply a driving current to the light emitting element ED.

The scanning transistor ST may be configured to control the electrical state of a corresponding node in the subpixel circuit SPC or to control the state or operation of the driving transistor DT.

The at least one capacitor may include a storage capacitor Cst to maintain a constant voltage during a frame.

To drive the subpixel SP, a data signal VDATA which is an image signal, a scanning signal SC which is a gate signal, and the like may be applied to the subpixel SP. Further, a common pixel driving voltage including a first common driving voltage VDD and a second common driving voltage VSS may be applied to the subpixel SP to drive the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed at each subpixel SP, and the common electrode CE may be an electrode disposed common to the plurality of subpixels SP. In an example, the pixel electrode PE may be an anode and the common electrode CE may be a cathode. In another example, the pixel electrode PE may be a cathode and the common electrode CE may be an anode. In the following, for the sake of brevity, a case in which the pixel electrode PE is an anode and the common electrode CE is a cathode is taken as an example.

When the light emitting element ED is an organic light emitting element, the intermediate layer EL may include an emission layer EML, a first common intermediate layer COM1 between the pixel electrode PE and the emission layer EML, and a second common intermediate layer COM2 between the emission layer EML and the common electrode CE. The first common intermediate layer COM1 and the second common intermediate layer COM2 are collectively referred to as a common intermediate layer EL_COM.

The emission layer EML may be disposed on each of the subpixels SP, and the common intermediate layer EL_COM may be disposed in common across the plurality of subpixels SP.

The emission layer EML may be disposed in respective emission areas, and the common intermediate layer EL_COM may be disposed in common across the plurality of emission and non-emission areas.

For example, the first common intermediate layer COM1 may include a hole injection layer HIL, a hole transfer layer HTL, and the like. The second common intermediate layer COM2 may include an electron transfer layer ETL, an electron injection layer EIL, and the like.

The hole injection layer may inject holes from the pixel electrode PE to the hole transfer layer, the hole transfer layer may transport holes to the emission layer EML, the electron injection layer may inject electrons from the common electrode CE to the electron transfer layer, and the electron transfer layer may transport electrons to the emission layer EML.

For example, the common electrode CE may be electrically connected to a second common driving voltage line VSSL. A second common driving voltage VSS, a type of common driving voltage, may be applied to the common electrode CE through the second common driving voltage line VSSL. The pixel electrode PE may be electrically connected directly or indirectly (via other transistors) to the first node N1 of the driving transistor DT of each of the subpixels SP. As used herein, the “second common driving voltage VSS” may also be referred to as a “base voltage”, and the “second common driving voltage line VSSL” may also be referred to as a “low potential supply voltage line” or a “base voltage line”.

Each of the light emitting elements ED may include the pixel electrode PE, the emission layer EML in the intermediate layer EL, and an overlapping portion of the common electrode CE. A predetermined emission area may be formed by each light emitting element ED. For example, the emission area of each light emitting element ED may include the pixel electrode PE, the emission layer in the intermediate layer EL, and an overlapping portion of the common electrode CE.

For example, the light emitting element ED may be an OLED, an inorganic-based light-emitting diode (LED), a quantum dot light emitting element, or the like. For example, when the light emitting element ED is an OLED, the intermediate layer EL in the light emitting element ED may include an intermediate layer including an organic material.

The driving transistor DT may be a driving transistor for supplying a driving current to the light emitting element ED. The driving transistor DT may be connected to the first common driving voltage line VDDL and the light emitting element ED.

The driving transistor DT may include a first node N1, a second node N2, and a third node N3. The first node N1 may be electrically connected to the light emitting element ED, a data signal VDATA may be applied to the second node N2, and a first common driving voltage VDD from the first common driving voltage line VDDL may be applied to the third node N3.

In the driving transistor DT, the second node N2 may be a gate node, the first node N1 may be a source node or a drain node, and the third node N3 may be a drain node or a source node. In the following, for the sake of brevity, a case in which the second node N2 is a gate node, the first node N1 is a source node, and the third node N3 is a drain node in the driving transistor DT is taken as an example.

The scanning transistor ST included in the subpixel circuit SPC illustrated in FIG. 2 may be a switching transistor for transferring a data signal VDATA, an image signal, to the second node N2 serving as the gate node of the driving transistor DT.

The scanning transistor ST may be controlled to turn on and off by a scanning signal SC, a gate signal applied through the scanning signal line SCL, a type of gate line GL, to control an electrical connection between the second node N2 of the driving transistor DT and the data line DL. The drain electrode or the source electrode of the scanning transistor ST may be electrically connected to the data line DL, the source electrode or the drain electrode of the scanning transistor ST may be electrically connected to the second node N2 of the driving transistor DT, and the gate electrode of the scanning transistor ST may be electrically connected to the scanning signal line SCL.

The storage capacitor Cst may be electrically connected to the first node N1 and the second node N2 of the driving transistor DT. The storage capacitor Cst may include a first capacitor electrode electrically connected to the first node N1 of the driving transistor DT or corresponding to the first node N1 of the driving transistor DT and a second capacitor electrode electrically connected to the second node N2 of the driving transistor DT or corresponding to the second node N2 of the driving transistor DT.

The storage capacitor Cst may be an external capacitor intentionally designed to be provided outside the driving transistor DT, rather than a parasitic capacitor (e.g., Cgs, Cgd), which is an internal capacitor present between the first node N1 and the second node N2 of the driving transistor DT.

Each of the driving transistor DT and the scanning transistor ST may be an n-type transistor or a p-type transistor.

The display panel 110 may have a top emission structure or a bottom emission structure.

When the display panel 110 has the top emission structure, at least a portion of the subpixel circuit SPC may overlap at least a portion of the light emitting element ED in a vertical direction. Accordingly, the area of the emission area may be increased and the aperture ratio may be increased.

When the display panel 110 has the bottom emission structure, the subpixel circuit SPC may not overlap the light emitting element ED in the vertical direction.

The subpixel circuit SPC may have a 2T1C structure including two transistors DT and ST and one capacitor Cst as shown in FIG. 2, and in some situations, may include one or more transistors and/or one or more capacitors.

For example, the subpixel circuit SPC may have an 8T1C structure including eight transistors and one capacitor. In another example, the subpixel circuit SPC may have a 6T2C structure including six transistors and two capacitors. In another example, the subpixel circuit SPC may have a 7T1C structure including seven transistors and one capacitor.

The type and number of gate signals supplied to gate lines connected to the subpixel SP may vary depending on the structure of the subpixel circuit SPC. The type and number of common pixel driving voltages supplied to the subpixel SP may also vary depending on the structure of the subpixel circuit SPC.

Because the circuit elements in the respective subpixels SP (in particular, the light emitting element ED implemented as an organic light-emitting diode (OLED) including an organic material) are susceptible to external moisture or oxygen, the encapsulation layer 200 may be disposed on the display panel 110 to prevent external moisture or oxygen from permeating into the circuit elements (particularly, the light emitting element ED). The encapsulation layer 200 may be configured in various forms to prevent the light emitting element ED from coming into contact with moisture or oxygen.

Referring to FIG. 2, the display device 100 according to embodiments may include a touch sensor layer 210 including a plurality of sensor electrodes for sensing a user's touch, a touch driver circuit 220 configured to sense the plurality of sensor electrodes, and a touch controller 230 configured to determine the presence of a touch or touch coordinates using sensing results (or touch sensing data) from the touch driver circuit 220.

The touch sensor layer 210 may be embedded in the display panel 110. For example, the touch sensor layer 210 may be disposed on the encapsulation layer 200 within the display panel 110.

The display panel 110 may further include a plurality of touch pads TP to which the touch driver circuit 220 is electrically connected and a plurality of touch routing lines TL for electrically connecting a plurality of sensor electrodes of the touch sensor layer 210 to the plurality of touch pads TP to which the touch driver circuit 220 is connected.

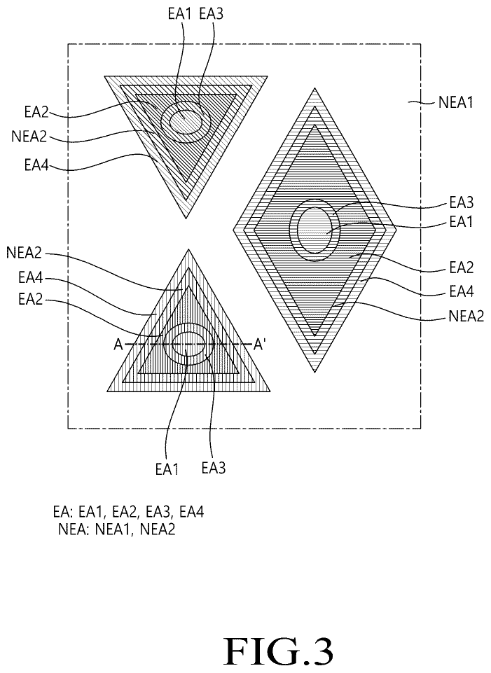

FIGS. 3 to 5 are example plan views illustrating subpixels arranged in an active area AA in the display device 100 according to embodiments.

Referring to FIG. 3, in the active area AA, a plurality of emission areas EA and a plurality of non-emission areas NEA surrounding the emission areas EA may be provided.

As shown in FIG. 3, the emission areas EA of at least two subpixels SP may have different area sizes, but embodiments are not limited thereto.

Referring to FIG. 3, the display device 100 according to embodiments may include a plurality of emission areas EA1, EA2, EA3, and EA4 and non-emission areas NEA1 and NEA2 surrounding the emission areas.

For example, a single subpixel may include a plurality of emission areas EA1, EA2, EA3, and EA4 and a non-emission areas NEA1 and NEA2 at least partially surrounding the emission areas.

In the at least one subpixel, the first emission area EA1 may be located at the center among the plurality of emission areas EA1, EA2, EA3, EA4. The second emission area EA2 may have a structure surrounding the first emission area EA1.

The third emission area EA3 may be located between the first emission area EA1 and the second emission area EA2. The third emission area EA3 may have a structure surrounding the first emission area EA1, and the second emission area EA2 may have a structure surrounding the third emission area EA3.

The second non-emission area NEA2 may have a structure surrounding the second emission area EA2. The third emission area EA3 may have a structure surrounding the first emission area EA1, the second emission area EA2 may have a structure surrounding the third emission area EA3, and the second non-emission area NEA2 may have a structure surrounding the second emission area EA2.

The fourth emission area EA4 may have a structure surrounding the second non-emission area NEA2. The third emission area EA3 may have a structure surrounding the first emission area EA1, the second emission area EA2 may have a structure surrounding the third emission area EA3, the second non-emission area NEA2 may have a structure surrounding the second emission area EA2, and the fourth emission area EA4 may have a structure surrounding the second non-emission area NEA2.

The first non-emission area NEA1 may have a structure surrounding the fourth emission area EA4. The third emission area EA3 may have a structure surrounding the first emission area EA1, the second emission area EA2 may have a structure surrounding the third emission area EA3, the second non-emission area NEA2 may have a structure surrounding the second emission area EA2, the fourth emission area EA4 may have a structure surrounding the second non-emission area NEA2, and the first non-emission area NEA1 may have a structure surrounding the fourth emission area EA4.

Referring to FIG. 3, the plurality of emission areas EA1, EA2, EA3, and EA4 disposed in a single subpixel may be spaced apart from the plurality of emission areas EA1, EA2, EA3, EA4 disposed in other adjacent subpixels.

The at least one first emission area EA1 disposed on the display panel 111 may be an area that emits red light, another first emission areas EA1 may be an area that emits green light, and further another first emission area EA1 may be an area that emits blue light, but embodiments are not limited thereto.

The second emission area EA2, the third emission area EA3, and the fourth emission area EA4 surrounding the first emission area EA1 that emits red light may emit red light, the second emission area EA2, the third emission area EA3, and the fourth emission area EA4 surrounding the first emission area EA1 that emits green light may emit green light, and the second emission area EA2, the third emission area EA3, and the fourth emission area EA4 surrounding the first emission area EA1 that emits blue light may emit blue light.

As shown in FIG. 3, in a single subpixel, the plurality of emission areas EA1, EA2, EA3, and EA4 may have different planar shapes. However, embodiments are not limited thereto, and the plurality of emission areas EA1, EA2, EA3, and EA4 may have the same planar shape. In addition, the second non-emission area NEA2 surrounding the second emission area EA2 may have a shape corresponding to the shape of the second emission area EA2. Embodiments are not limited thereto.

The plurality of emission areas EA1, EA2, EA3, and EA4 may have a planar shape corresponding to one of a circular shape, an elliptical shape, or a polygonal shape, or combinations thereof. The polygonal shape may be, for example, a triangular shape, a quadrangular shape, a pentagonal shape, a hexagonal shape, or any combination thereof. Embodiments are not limited thereto.

For example, in a single subpixel, the first emission area EA1 and the third emission area EA3 may have an elliptical planar shape, and the second emission area EA2 and the fourth emission area EA4 may have a triangular planar shape.

In another subpixel, the first emission area EA1 and the third emission area EA3 may have an elliptical planar shape, and the second emission area EA2 and the fourth emission area EA4 may have a rhombic shape that is a quadrangular planar shape.

As shown in FIG. 3, in the plurality of subpixels, the first emission areas EA1 and the third emission areas EA3 may have an elliptical planar shape. That is, in the plurality of subpixels, the first emission areas EA1 may have the same planar shape, and the third emission areas EA3 may have the same planar shape.

In the plurality of subpixels, one subpixel may be configured such that the second emission area EA2 and the fourth emission area EA4 have a triangular planar shape, and another subpixel may be configured such that the second emission area EA2 and the fourth emission area EA4 have a rhombic shape that is a quadrangular planar shape. That is, in the plurality of subpixels, the second emission areas EA2 may have different planar shapes, and the fourth emission areas EA4 may have different planar shapes.

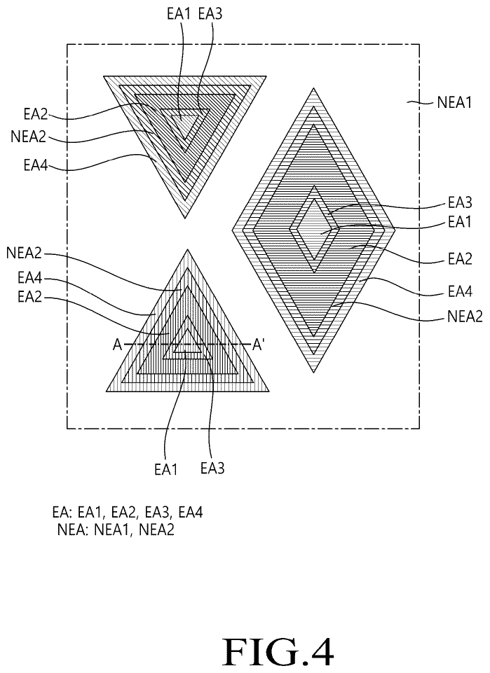

FIG. 4 is an example plan view illustrating a subpixel disposed in the active area AA in the display device 100 according to embodiments of the present disclosure.

Referring to FIG. 4, a plurality of emission areas EA and a plurality of non-emission areas NEA may be disposed in the active area AA. The display device 100 according to embodiments of the present disclosure may include a plurality of emission areas EA1, EA2, EA3, and EA4 and non-emission areas NEA1 and NEA2 surrounding at least one of the plurality of emission areas EA1, EA2, EA3, and EA4.

Referring to FIG. 4, in a single subpixel, the plurality of emission areas EA1, EA2, EA3, and EA4 may have the same planar shape. In this case, the plurality of subpixels may have emission areas of different planar shapes.

For example, in a single subpixel, the first emission area EA1, the second emission area EA2, the third emission area EA3, and the fourth emission area EA4 may have a triangular planar shape.

In another subpixel, the first emission area EA1, the second emission area EA2, the third emission area EA3, and the fourth emission area EA4 may have a rhombic shape that is a quadrangular planar shape.

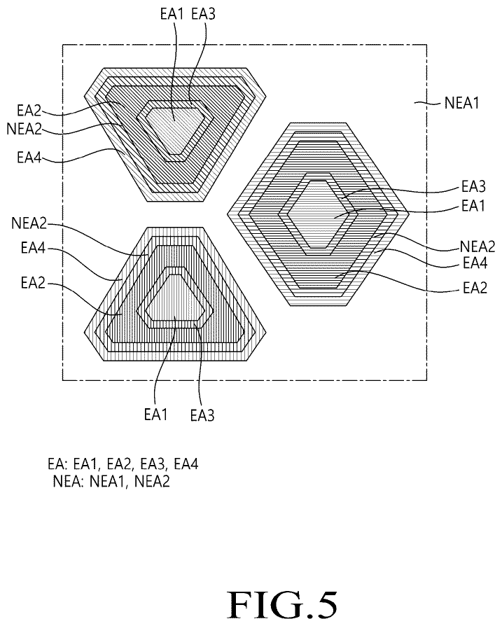

FIG. 5 is another example plan view illustrating a subpixel disposed in the active area AA in the display device 100 according to embodiments of the present disclosure.

Referring to FIG. 5, a plurality of emission areas EA and a plurality of non-emission areas NEA may be disposed in the active area AA. The display device 100 according to embodiments may include a plurality of emission areas EA1, EA2, EA3, and EA4 and non-emission areas NEA1 and NEA2 surrounding at least one of the plurality of emission areas EA1, EA2, EA3, and EA4.

Referring to FIG. 5, in the plurality of subpixels, the plurality of emission areas EA1, EA2, EA3, and EA4 may have the same planar shape.

For example, in a single subpixel, the first emission area EA1, the second emission area EA2, the third emission area EA3, and the fourth emission area EA4 may have a hexagonal planar shape.

In another subpixel, the first emission area EA1, the second emission area EA2, the third emission area EA3, and the fourth emission area EA4 may have a hexagonal planar shape.

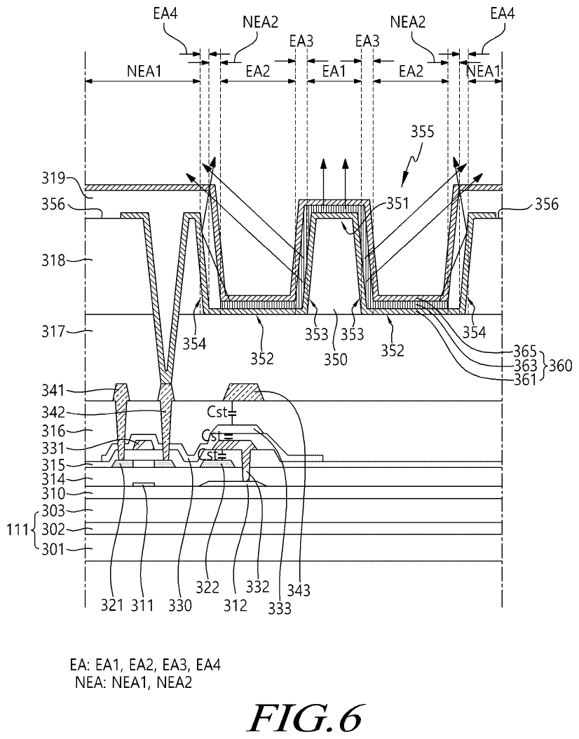

FIG. 6 is an example cross-sectional view taken along A-A′ line of FIG. 3 according to embodiments of the present disclosure.

Referring to FIG. 6, a transistor disposed over the substrate 111 and a light emitting element 360 electrically connected to the transistor may be disposed in the active area AA.

The transistor includes an active layer 321, a gate electrode 331, a source electrode 342, and a drain electrode 341.

The light emitting element 360 includes a first electrode 361, an emission layer 363, and a second electrode 365. Here, the first electrode 361 may be a pixel electrode and the second electrode 365 may be a common electrode. For example, the pixel electrode may be an anode electrode and the common electrode may be a cathode electrode. In another example, the pixel electrode may be a cathode electrode and the common electrode may be an anode electrode. In the following, for the sake of brevity, a case in which the pixel electrode is an anode electrode and the common electrode is a cathode electrode is taken as an example, but embodiments are not limited thereto.

Referring to FIG. 6, the substrate 111 may include a first substrate 301 and a second substrate 303 and may include an intermediate layer 302 between the first substrate 301 and the second substrate 303. Here, the intermediate layer 302 may be an inorganic film, and may block moisture permeation. However, the structure of the substrate 111 is not limited thereto, and may have a single-layer structure rather than a structure having a plurality of layers.

The first buffer layer 310 disposed over the substrate 111 may be a single film or a plurality of films.

A light shield 311 may be disposed over the first buffer layer 310.

A second buffer layer 314 may be disposed over the light shield 311.

An active layer 321 and a first storage capacitor electrode 322 may be disposed over the second buffer layer 314. The active layer 321 according to embodiments may include a channel region that may overlap at least a portion of the light shield 311 and may overlap the gate electrode 331.

The remaining region of the active layer 321, except for the channel region, may be a region in which the active layer 321 is conductorized. Such an active layer 321 may include an oxide semiconductor material.

A first storage capacitor electrode 322 may be disposed on the same layer as the active layer 321. The first storage capacitor electrode 322 may have a state in which the oxide semiconductor material is conductorized, but embodiments are not limited thereto.

A gate insulating film 315 may be disposed between the active layer 321 and the first storage capacitor electrode 322.

A gate electrode 331 and a second storage capacitor electrode 332 may be disposed over the gate insulating film 315.

The gate electrode 331 may overlap the channel region of the active layer 321, and the second storage capacitor electrode 332 may overlap the first storage capacitor electrode 322. The second storage capacitor electrode 332 may be electrically connected to a metal layer 312 disposed on the same layer as the light shield 311, but embodiments are not limited thereto.

An interlayer insulating film 330 may be disposed over the gate electrode 331 and the second storage capacitor electrode 332.

A third storage capacitor electrode 333 may be disposed over the interlayer insulating film 330. The third storage capacitor electrode 333 may overlap the second storage capacitor electrode 332.

A passivation layer 316 may be disposed over the third storage capacitor electrode 333. The passivation layer 316 may include an organic insulating material or an inorganic insulating material.

The source electrode 342, the drain electrode 341, and the fourth storage capacitor electrode 343 may be disposed over the passivation layer 316.

The source electrode 342 and the drain electrode 341 may be spaced apart from each other and electrically connected to the conductorized region of the active layer 321.

The fourth storage capacitor electrode 343 may overlap the third storage capacitor electrode 333.

Referring to FIG. 6, the first to fourth storage capacitor electrodes 322, 332, 333, and 343 may be arranged to overlap each other and form a storage capacitor Cst.

A first insulating layer 317 may be disposed over the source electrode 342, the drain electrode 341, and the fourth storage capacitor electrode 343.

The first insulating layer 317 may serve to planarize the surface of the substrate 111. The first insulating layer 317 may include an organic insulating material or an inorganic insulating material, but embodiments are not limited thereto.

A second insulating layer 318 may be disposed over the first insulating layer 317. The second insulating layer 318 may include an organic insulating material or an inorganic insulating material, but embodiments are not limited thereto.

Referring to FIG. 6, the first insulating layer 317 and the second insulating layer 318 may include a single hole in an area overlapping a portion of the top surface of the source electrode 342 of the transistor.

Referring to FIG. 6, the second insulating layer 318 may include a recess 355 exposing a portion of the top surface of the first insulating layer 317. The second insulating layer 318 may include a peripheral portion 356 extending from the recess 355.

The recess 355 may include a flat portion 352 and an inclined portion 354 extending from the flat portion 352 and surrounding the flat portion 352. The peripheral portion 356 of the second insulating layer 318 may extend from the inclined portion 354 of the recess 355.

The recess 355 may have a planar shape corresponding to one of a circular shape, an elliptical shape, or a polygonal shape, or combinations thereof. The polygonal shape may be, for example, a triangular shape, a quadrangular shape, a pentagonal shape, a hexagonal shape, or a combination thereof.

The recess 355 may expose a portion of the top surface of the first insulating layer 317. The flat portion 352 of the recess 355 may correspond to a portion of the top surface of the first insulating layer 317.

A protruding pattern 350 may be disposed within the recess 355. The protruding pattern 350 may be disposed as an island within the recess 355. For example, the protruding pattern 350 may be disposed within the recess 355 and be spaced apart from the inclined portion 354 of the recess 355. For example, within one subpixel, the protruding pattern 350 may be spaced apart from the inclined portion 354 of the recess 355.

The protruding pattern 350 may have a roughly columnar protruding shape. The protruding pattern 350 may be disposed within the recess 355 and may have a tapered column shape. The protruding pattern 350 may have a column shape including an inclined portion 353 and a top surface 351.

Referring to FIG. 6, a single subpixel region may include a plurality of emission areas EA and a plurality of non-emission areas NEA. The plurality of emission areas may include a first emission area EA1, a second emission area EA2, a third emission area EA3, and a fourth emission area EA4. The non-emission areas NEA may include a first non-emission area NEA1 and a second non-emission area NEA2.

The first emission area EA1 may correspond to an area overlapping the top surface 351 of the protruding pattern 350. The second emission area EA2 may correspond to an area overlapping the flat surface 352 of the recess 355. In a plane, the second emission area EA2 may be disposed in a shape surrounding the first emission area EA1. For example, in a plane, the flat portion 352 of the recess 355 may be disposed in a shape surrounding the top surface 351 of the protruding pattern 350.

The third emission area EA3 may correspond to an area overlapping the inclined portion 353 of the protruding pattern 350. In a plane, the third emission area EA3 may be located between the first emission area EA1 and the second emission area EA2. That is, in a plane, the third emission area EA1 may be disposed in a shape surrounding the third emission area EA1, and the second emission area EA2 may be disposed in a shape surrounding the third emission area EA3.

The second non-emission area NEA2 may correspond to an area in the flat portion 352 of the recess 355 where the area in which the first electrode 361 is disposed overlaps the area in which the emission layer 363 is not disposed. For example, the second non-emission area NEA2 may correspond to an area overlapping a bank 319 disposed on the flat portion 352 of the recess 355. In a plane, the third emission area EA3 may be disposed in a shape surrounding the first emission area EA1, the second emission area EA2 may be disposed in a shape surrounding the third emission area EA3, and the second non-emission area NEA2 may be disposed in a shape surrounding the second emission area EA2.

The fourth emission area EA4 may correspond to an area overlapping the inclined portion 354 of the recess 355. The fourth emission area EA4 may be an area where light reflected by the inclined portion 354 is extracted to the outside. The fourth emission area EA4 may be an area where light emitted from the emission layer 363 is reflected by the first electrode 361 disposed on the inclined portion 354 and extracted to the outside. In a plane, the fourth emission area EA4 may be disposed in a shape surrounding the second non-emission area NEA2. For example, in a plane, the third emission area EA3 may be disposed in a shape surrounding the first emission area EA1, the second emission area EA2 may be disposed in a shape surrounding the third emission area EA3, the second non-emission area NEA2 may be disposed in a shape surrounding the second emission area EA2, and the fourth emission area EA4 may be disposed in a shape surrounding the second non-emission area NEA2.

The first non-emission area NEA1 may correspond to an area excluding the emission area EA and the second non-emission area NEA2. In a plane, the first non-emission area NEA1 may be disposed in a shape surrounding the fourth emission area EA4. For example, the first non-emission area NEA1 may be disposed in a shape surrounding the emission area EA and the second non-emission area NEA2.

In the display device 100 according to embodiments, the emission area EA located in the active area AA may include a main emission area and a secondary emission area. The main emission area may be an area corresponding to an overlapping area in which the first electrode 361, the emission layer 365, and the second electrode 362 are sequentially stacked on each other. The main emission area may be an area where light emitted from the emission layer 365 is extracted from an open area to the outside. The secondary emission area may be an area where light reflected by an inclined surface is emitted. The secondary emission area may be an area where light emitted from the emission layer 365 is reflected by the first electrode 361 disposed on the inclined surface of the second insulating layer 318 and extracted to the outside. In the display device 100 according to embodiments, the first to third emission areas EA1, EA2, and EA3 may be main emission areas. For example, the fourth emission area EA4 may be a secondary emission area.

The protruding pattern 350 may have a planar shape corresponding to one of a circular shape, an elliptical shape, or a polygonal shape, or combinations thereof. The polygonal shape may be, for example, a triangular shape, a quadrangular shape, a pentagonal shape, a hexagonal shape, or a combination thereof.

The protruding pattern 350 and the recess 355 may have planar shapes corresponding to each other. For example, the protruding pattern 350 and the recess 355 may have the same planar shape corresponding to a circular shape, an elliptical shape, or a polygonal shape.

In addition, the protruding pattern 350 and the recess 355 may have planar shapes that do not correspond to each other. For example, the protruding pattern 350 may have a planar shape corresponding to an elliptical shape, and the recess 355 may have a planar shape corresponding to a polygonal shape.

The protruding pattern 350 may include an organic insulating material or an inorganic insulating material, but embodiments are not limited thereto.

The protruding pattern 350 may be formed substantially at the same time in the same process as the second insulating layer 318. In this case, the protruding pattern 350 may include the same material as the second insulating layer 318.

In another example, the protruding pattern 350 may be formed in a different process than the second insulating layer 318. The protruding pattern 350 may be formed after the second insulating layer 318 having the recess 355 is formed. In this case, the protruding pattern 350 may include the same material as the second insulating layer 318 or a different material than the second insulating layer 318.

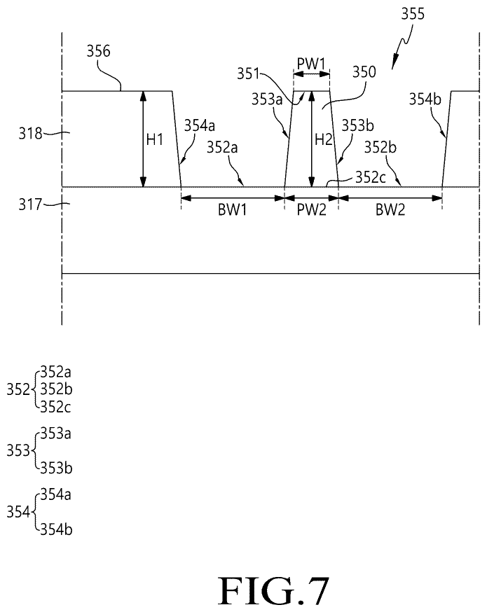

In the followings, the protruding pattern 350 will be described in detail with reference to FIG. 7.

FIG. 7 is an example cross-sectional view illustrating the protruding pattern 350 shown in FIG. 6 according to one embodiment.

Referring to FIG. 7, the height of the second insulating layer 318 may be a first height H1, and the height of the protruding pattern 350 may be a second height H2. The second height H2, i.e., the height of the protruding pattern 350, may correspond to the first height H1, i.e., the height of the second insulating layer 318.

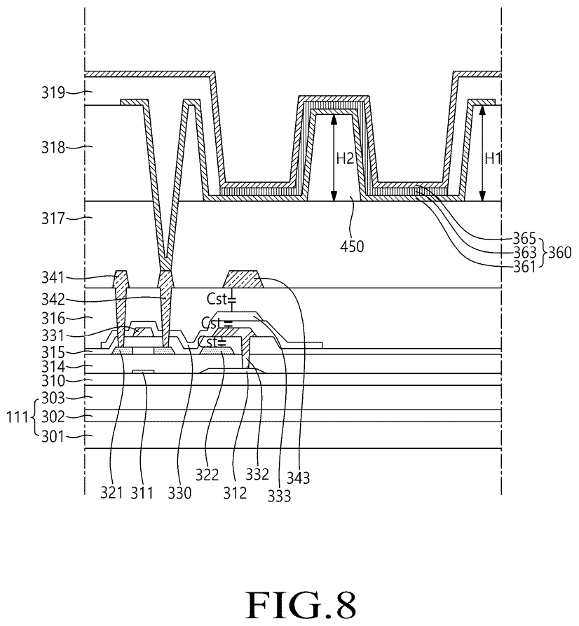

Referring to FIG. 8, the second height H2, i.e., the height of the protruding pattern 450 of the second insulating layer 318, may be different from the first height H1, i.e., the height of the second insulating layer 318. In an example, the second height H2, i.e., the height of the protruding pattern 450, may lower than the first height H1, i.e., the height of the second insulating layer 318. In another example, the second height H2, i.e., the height of the protruding pattern 450 of the second insulating layer 318, may be higher than the first height H1, i.e., the height of the second insulating layer 318.

Referring to FIG. 7, the protruding pattern 350 may include a bottom surface 352c located over the first insulating layer 317 within the recess 355, an inclined portion 353 extending from the bottom surface 352c, and a top surface 351 extending from the inclined portion 353.

The top surface 351 of the protruding pattern 350 may have a planar shape corresponding to one of a circular shape, an elliptical shape, or a polygonal shape, or combinations thereof. The polygonal shape may be, for example, a triangular shape, a quadrangular shape, a pentagonal shape, a hexagonal shape, or any combination thereof.

The bottom surface 352c of the protruding pattern 350 may have a planar shape corresponding to one of a circular shape, an elliptical shape, or a polygonal shape, or combinations thereof. The polygonal shape may be, for example, a triangular shape, a quadrangular shape, a pentagonal shape, a hexagonal shape, or any combination thereof.

The top surface 351 and the bottom surface 352c of the protruding pattern 350 may have corresponding planar shapes.

Referring to FIG. 7, the width of the top surface 351 of the protruding pattern 350 may be a first width PW1, and the width of the bottom surface 352c of the protruding pattern 350 may be a second width PW2.

The first width PW1, i.e., the width of the top surface 351 of the protruding pattern 350, may be smaller than the second width PW2, i.e., the width of the bottom surface 352c of the protruding pattern 350. That is, the protruding pattern 350 may have a regularly tapered column shape with the inclined portion 353 extending from the bottom surface 352c to the top surface 351.

For example, because the respective subpixels of the plurality of subpixels may have different widths, the respective protruding patterns of the plurality of protruding patterns 350 of the subpixels may have different first widths PW1. The respective protruding patterns of the plurality of protruding patterns 350 of the subpixels may also have different second widths PW2. Embodiments are not limited thereto.

Referring to FIG. 7, the protruding pattern 350 may be disposed on the first insulating layer 317 within the recess 355.

A first flat portion 352a of the recess 355 located between an inclined portion 354a located on a first side of the recess 355 and an inclined portion 353a located on a first side of the protruding pattern 350 may have a first width BW1. A second flat portion 352b of the recess 355 located between the inclined portion 354b located on a second side of the recess 355 and the inclined portion 353b located on a second side of the protruding pattern 350 may have a second width BW2.

Referring to FIG. 7, the center of the protruding pattern 350 and the center of the recess 355 may be located at points corresponding to each other. That is, the first width BW1 of the first flat portion 352a and the second width BW2 of the second flat portion 352b may have the same width size as each other. In this case, the protruding pattern 350 may be disposed as an island within the recess 355, spaced apart by the first width BW1 or the second width BW2 with respect to the inclined portion 354a or 354b of the recess 355. For example, the protruding pattern 350 may be symmetrically disposed within the recess 355 in a plane. For example, the protruding pattern 350 may be symmetrically disposed within a subpixel to have a uniform luminous efficiency.

Referring to FIG. 7, the center of the protruding pattern 350 and the center of the recess 355 may be located at points that do not correspond to each other. That is, the first width BW1 of the first flat portion 352a and the second width BW2 of the second flat portion 352b may have different width sizes. In this case, the protruding pattern 350 may be disposed as an island within the recess 355, spaced apart by the first width BW1 or the second width BW2 with respect to the inclined portion 354a or 354b of the recess 355. For example, the protruding pattern 350 may be disposed asymmetrically within the recess 355 in a plane. Referring to FIG. 6, the light emitting element 360 including the first electrode 361, the emission layer 363, and the second electrode 365 may be disposed over the second insulating layer 318.

The first electrode 361 may include parallel portions which are parallel to the surface of the substrate 111 in areas overlapping the flat portion 352 of the recess 355 and the top surface 351 of the protruding pattern 350 and inclined portions which extend over the inclined portion 354 of the recess 355 and the inclined portion 353 of the protruding pattern 350 and have predetermined angles to the surface of the substrate 111.

Referring to FIG. 6, the first electrode 361 may be disposed in the first emission area EA1, the second emission area EA2, the third emission area EA3, the fourth emission area EA4, and a portion of the second non-emission area NEA2, and a portion of the first non-emission area NEA1.

Referring to FIG. 6, in at least one subpixel area, the transistor may be electrically connected to the first electrode 361 of the light emitting element 360 through a contact hole penetrating the first insulating layer 317 and the second insulating layer 318. For example, the source electrode 342 or the drain electrode 341 of the transistor may be electrically connected to the first electrode 361 of the light emitting element 360 through a contact hole penetrating the first insulating layer 317 and the second insulating layer 318.

Referring to FIG. 6, the bank 319 may be disposed over a portion of the second insulating layer 318 and a portion of the first electrode 361. The bank 319 may be disposed such that the portion of the first electrode 361 disposed within the recess 355 of the second insulating layer 318 and a portion of the first electrode 361 disposed on the top surface 351 and the inclined portion 353 of the protruding pattern 350 are exposed. The bank 319 may have an open area of the subpixel.

The banks 319 may be disposed to have a planar shape corresponding to the top surface shape of the second insulating layer 318.

The bank 319 may have a flat top surface or a convex top surface. For example, as shown in FIG. 6, the bank 319 may have a flat top surface parallel to the substrate 111.

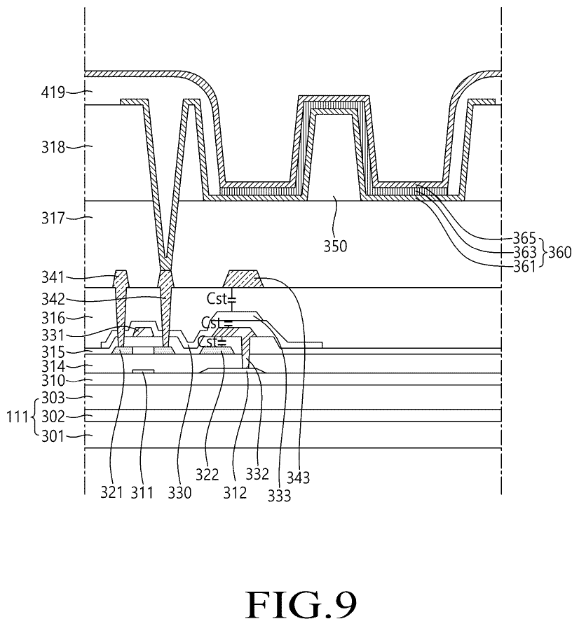

In another example, as shown in FIG. 9, the bank 419 may have a convex top surface.

A spacer may be disposed on a portion of the top surface of the bank 319 or 419. The spacer may be disposed in the non-emission area NEA.

The emission layer 363 of the light emitting element 360 may be disposed over the substrate 111 on which the first electrode 361 is disposed.

The emission layer 363 may be disposed over the first electrode 361 within the open area of the bank 319.

Referring to FIG. 6, within the open area of the bank 319, the emission layer 363 may be disposed over the first electrode 361 in areas overlapping the flat portion 352 of the recess 355, the top surface 351 of the protruding pattern 350, and the inclined portion 353.

Referring to FIG. 6, the emission layer 363 may be disposed in the first emission area EA1, the second emission area EA2, and the third emission area EA3.

Referring to FIG. 6, the second electrode 365 of the light emitting element 360 may be disposed over the substrate 111 on which the emission layer 363 is disposed.

The second electrode 365 may be disposed in the entirety of the first emission area EA1, the second emission area EA2, the third emission area EA3, the fourth emission area EA4, the second non-emission area NEA2, and the first non-emission area NEA1.

The second electrode 365 may be disposed on the top surface of the emission layer 363 and may also be disposed in an area where the emission layer 363 is not disposed.

The first electrode 361 of the light emitting element 360 may include a reflective material. The first electrode 361 may include at least one of aluminum (Al), neodymium (Nd), nickel (Ni), titanium (Ti), tantalum (Ta), copper (Cu), silver (Ag), or an alloy thereof, but embodiments are not limited thereto.

The second electrode 365 may include a conductive material capable of transmitting or semi-transmitting light. For example, the second electrode 365 may include at least one type of transparent conductive oxide, such as indium tin oxide (ITO), indium zinc oxide (IZO), indium tin zinc oxide (ITZO), zinc oxide, or tin oxide, or may include a semi-transparent metal, such as magnesium (Mg), silver (Ag), or an alloy of Mg and Ag. Here, when the second electrode 365 includes a semi-transparent metal, the thickness of the second electrode 365 may be less than the thickness of the first electrode 361.

Referring to FIG. 6, the first emission area EA1 may be an area where a portion of light emitted from the emission layer 363 disposed on the top surface 351 of the protruding pattern 350 is extracted from the panel in a direction perpendicular to the substrate 111 through the emission layer 363 and the second electrode 365. The first emission area EA1 may also be an area where a portion of the light emitted from the emission layer 363 disposed on the top surface 351 of the protruding pattern 350 reaches the first electrode 361, is reflected by the first electrode 361, and is extracted from the panel in a direction perpendicular to the substrate 111 through the emission layer 363 and the second electrode 365.

The second emission area EA2 may be an area where a portion of light emitted from the emission layer 363 disposed in the flat portion 352 of the recess 355 is extracted from the panel in a direction perpendicular to the substrate 111 through the emission layer 363 and the second electrode 365. The second emission area EA2 may also be an area where a portion of the light emitted from the emission layer 363 disposed in the flat portion 352 of the recess 355 reaches the first electrode 361, is reflected by the first electrode 361, and is extracted from the panel in a direction perpendicular to the substrate 111 through the emission layer 363 and the second electrode 365.

The third emission area EA3 may be an area where a portion of light emitted from the emission layer 363 disposed on the inclined portion 353 of the protruding pattern 350 is extracted from the panel in a direction perpendicular to the substrate 111 through the emission layer 363 and the second electrode 365. The third emission area EA3 may also be an area where a portion of light emitted from the emission layer 363 disposed on the inclined portion 353 of the protruding pattern 350 reaches the first electrode 361, is reflected by the first electrode 361, and is extracted from the panel in a direction perpendicular to the substrate 111 through the emission layer 363 and the second electrode 365.

The fourth emission area EA4 may be an area where a portion of the light emitted from the emission layer 363 disposed on the inclined portion 353 of the protruding pattern 350 is extracted from the panel in a direction inclined to the substrate 111 through the emission layer 363 and the second electrode 365. The fourth emission area EA4 may also be an area where a portion of light emitted from the emission layer 363 disposed on the inclined portion 353 of the protruding pattern 350 reaches the first electrode 361, is reflected by the first electrode 361, and is extracted from the panel in an inclined direction with respect to the substrate 111 through the emission layer 363 and the second electrode 365. The fourth emission area EA4 may also be an area where a portion of light emitted from the emission layer 363 disposed on the flat portion 352 of the recess 355 is reflected by the first electrode 361 disposed on the inclined portion 354 of the recess 355 through the emission layer 363 and the second electrode 365 and is extracted from the panel through the bank 319 and the second electrode 365.

Referring to FIG. 6, the display device 100 according to embodiments may include the protruding pattern 350 within the recess 355 in at least one subpixel such that light emitted from the emission layer 363 may be extracted from the panel in a direction perpendicular to the substrate 111, thereby improving light extraction efficiency. The protruding pattern 350 provided in the recess 355 may allow light emitted from the emission layer 363 to be extracted from the panel in a direction inclined to the substrate 111, thereby improving light extraction efficiency. In addition, the protruding pattern 350 provided within the recess 355 may allow light emitted from the emission layer 363 to be reflected by the first electrode 361 and extracted from the panel, thereby improving light extraction efficiency and luminance in the side viewing angle direction.

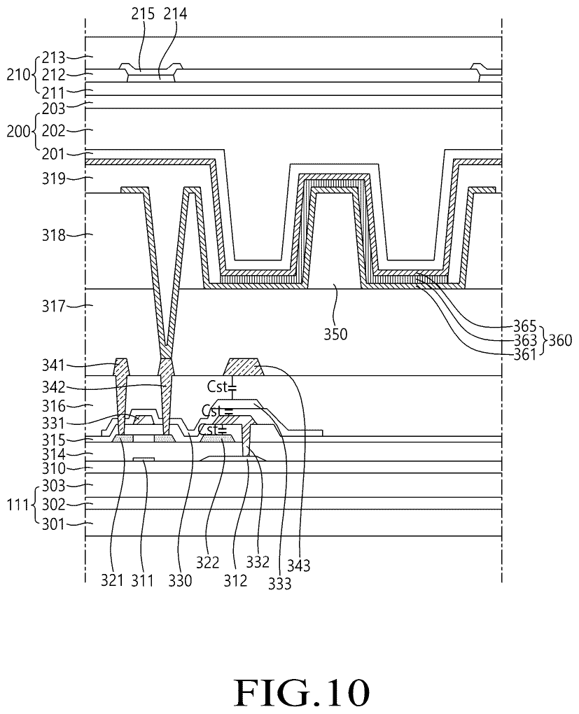

FIG. 10 is another example cross-sectional view taken along line A-A′ of FIG. 3 according to embodiments of the present disclosure. In the following description, features which are the same as or similar to those described above with reference to FIG. 1 to FIG. 9 will be omitted or briefly described.

Referring now to FIG. 10, the display device 100 according to embodiments may include the substrate 111, a transistor disposed on the substrate 111, the light emitting element 360 electrically connected to the transistor, the first insulating layer 317, the second insulating layer 318, the bank 319, the recess 355, and the protruding pattern 350.

The display device 100 according to embodiments may include the encapsulation layer 200.

Referring to FIG. 10, the encapsulation layer 200 may be located over the second electrode 365 of the light emitting element 360.

The encapsulation layer 200 may be a layer that prevents or at least reduces moisture or oxygen from permeating into the light emitting element 360 disposed under the encapsulation layer 200. The encapsulation layer 200 may prevent moisture or oxygen from permeating into the emission layer 363. Here, the encapsulation layer 200 may be implemented as a single film or a structure of a plurality of films.

Referring to FIG. 10, the encapsulation layer 200 may include a first encapsulation layer 201, a second encapsulation layer 202, and a third encapsulation layer 203. Each of the first encapsulation layer 201 and the third encapsulation layer 203 may be an inorganic film including an inorganic insulating material, and the second encapsulation layer 202 may be an organic film including an organic insulating material.

The second encapsulation layer 202 formed of an organic film may also serve as a planarizing layer.

The display device 100 according to embodiments may include a touch sensor layer 210.

Referring to FIG. 10, the touch sensor layer 210 may be located over the encapsulation layer 200.

The touch sensor layer 210 may include a bridge metal 214 and a touch sensor metal 215. The touch sensor layer 210 may further include insulating film components, such as a touch buffer layer 211, a touch interlayer insulating layer 212, and a touch passivation layer 213.

The touch buffer layer 211 may be disposed over the encapsulation layer 200. The bridge metal 214 may be disposed over the touch buffer layer 211, and the touch interlayer insulation layer 212 may be disposed over the bridge metal 214.

The touch sensor metal 215 may be disposed over the touch interlayer insulation layer 212. A portion of the touch sensor metal 215 may be connected to the corresponding bridge metal 214 through a hole in the touch interlayer insulating layer 212.

Referring to FIG. 10, the touch sensor metal 215 and the bridge metal 214 may be disposed in an area overlapping the bank 319. That is, each of the touch sensor metal 215 and the bridge metal 214 may be disposed so as not to overlap the emission area EA.

A plurality of touch sensor metals 215 may be provided to form a single touch electrode (or a single line of touch electrodes) and may be arranged in a mesh shape and electrically connected to each other. At least one of the touch sensor metals 215 and at least one other of the touch sensor metals 215 may be electrically connected by the bridge metal 214 to form a single touch electrode (or a single line of touch electrodes).

In a case where the display device 100 according to embodiments is of an in-cell type in which the touch sensor layer 210 is embedded, at least a portion of the touch sensor metal 215 located over the encapsulation layer 200 in the active area AA may extend to be disposed along the outer inclined surface of the encapsulation layer 200 to be electrically connected to a pad located further outward than the outer inclined surface of the encapsulation layer 200.

The display device 100 according to embodiments may further include a color filter provided over the encapsulation layer 200 or over the touch sensor layer 210. The color filter may be located to correspond to the respective subpixels.

The above-described embodiments of the present disclosure are briefly reviewed as follows.

A display device according to embodiments may include: a substrate including a subpixel including a plurality of emission areas; a first insulating layer disposed over the substrate; a second insulating layer disposed over the first insulating layer, and including a recess in the subpixel; a protruding pattern disposed within the recess; a first electrode disposed over the second insulating layer, and overlapping the recess and the protruding pattern; a bank disposed over a top surface of the first electrode and the second insulating layer, and including an open area in the subpixel; an emission layer disposed over the first electrode; and a second electrode disposed over the emission layer.

In the display device according to embodiments, a height of the protruding pattern may correspond to a height of the second insulating layer.

In the display device according to embodiments, a height of the protruding pattern may be lower than a height of the second insulating layer.

In the display device according to embodiments, the protruding pattern may have a planar shape corresponding to a circular shape, an elliptical shape, or a polygonal shape.

In the display device according to embodiments, the protruding pattern may have a planar shape corresponding to the planar shape of the recess.

In the display device according to embodiments, the protruding pattern may include the same material as the second insulating layer.

In the display device according to embodiments, a shape of a top surface of the protruding pattern may correspond to a shape of a bottom surface of the protruding pattern, and a width of the top surface of the protruding pattern may be smaller than a width of the bottom surface of the protruding pattern.

In the display device according to embodiments, a center of the protruding pattern and a center of the recess may be located at corresponding points.

In the display device according to embodiments, a center of the protruding pattern and a center of the recess may be located at points that do not correspond to each other.

In the display device according to embodiments, the plurality of emission areas may include a first emission area and a second emission area surrounding the first emission area.

In the display device according to embodiments, the first emission area may correspond to an area overlapping a top surface of the protruding pattern, and the second emission area may correspond to an area overlapping a flat portion of the recess.

In the display device according to embodiments, the plurality of emission areas may further include a third emission area located between the first emission area and the second emission area. The third emission area may correspond to an area overlapping an inclined portion of the protruding pattern.

In the display device according to embodiments, the subpixel may further include a second non-emission area surrounding the second emission area. The second non-emission area may correspond to an area overlapping a bank disposed on a flat portion of the recess.

In the display device according to embodiments, the subpixel further may include a fourth emission area surrounding the second non-emission area. The fourth emission area may correspond to an area overlapping an inclined portion of the recess.

In the display device according to embodiments, a shape of a top surface of the bank may correspond to a shape of a top surface of the second insulating layer.

In the display device according to embodiments, a top surface of the bank may have a flat shape or a convex shape. In the display device according to embodiments, the subpixel may further include a transistor, in which the first electrode and the transistor may be electrically connected to each other through a contact hole penetrating the first insulating layer and the second insulating layer.

In the display device according to embodiments, the transistor may include an active layer, a gate electrode, a source electrode, and a drain electrode, in which the first electrode may be electrically connected to the source electrode or the drain electrode.

In the display device according to embodiments, the display device may further include: an encapsulation layer disposed over the second electrode; and a touch sensor layer disposed over the encapsulation layer.

In the display device according to embodiments, the encapsulation layer may include: a first encapsulation layer including an inorganic insulating material; a second encapsulation layer located over the first encapsulation layer, and including an organic insulating material; and a third encapsulation layer located over the second encapsulation layer, and including an inorganic insulating material.

In the display device according to embodiments, the touch sensor layer may include: a touch buffer layer disposed over the encapsulation layer; a touch electrode located over the touch buffer layer, and disposed so as not to overlap the recess; and a touch passivation layer disposed over the touch electrode.

A display device according to embodiments includes: a substrate including a subpixel disposed in an active area; a first emission area located in the subpixel; a third emission area located in the subpixel and surrounding the first emission area; a second emission area located in the subpixel and surrounding the third emission area; a second non-emission area located in the subpixel and surrounding the second emission area; and a fourth emission area located in the subpixel and surrounding the second non-emission area, wherein a recess is disposed in the subpixel, and a protruding pattern is disposed within the recess.

According to the embodiments as set forth above, the display device may include the protruding pattern in the subpixel to improve light extraction efficiency.

According to the embodiments, the display device may include the protruding pattern to improve brightness in the direction of a side viewing angle.

According to the embodiments, the display device may operate at low power consumption due to improve light extraction efficiency and improved brightness in the direction of a side viewing angle.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a substrate comprising a subpixel including a plurality of emission areas;
a first insulating layer over the substrate;
a second insulating layer over the first insulating layer, the second insulating layer comprising a recess in the subpixel;
a protruding pattern within the recess;
a first electrode over the second insulating layer, the first electrode overlapping the recess and the protruding pattern;
a bank over a top surface of the first electrode and the second insulating layer, the bank comprising an open area in the subpixel;
an emission layer over the first electrode; and
a second electrode over the emission layer.

2. The display device of claim 1, wherein a height of the protruding pattern corresponds to a height of the second insulating layer.

3. The display device of claim 1, wherein a height of the protruding pattern is lower than a height of the second insulating layer.

4. The display device of claim 1, wherein the protruding pattern has a planar shape corresponding to a circular shape, an elliptical shape, or a polygonal shape.

5. The display device of claim 1, wherein the protruding pattern has a planar shape corresponding to a planar shape of the recess.

6. The display device of claim 1, wherein the protruding pattern comprises a same material as the second insulating layer.

7. The display device of claim 1, wherein a shape of a top surface of the protruding pattern corresponds to a shape of a bottom surface of the protruding pattern and a width of the top surface of the protruding pattern is smaller than a width of the bottom surface of the protruding pattern.

8. The display device of claim 1, wherein a center of the protruding pattern and a center of the recess are located at corresponding points.

9. The display device of claim 1, wherein a center of the protruding pattern and a center of the recess are located at points that do not correspond to each other.

10. The display device of claim 1, wherein the plurality of emission areas comprise a first emission area and a second emission area that surrounds the first emission area.

11. The display device of claim 10, wherein the first emission area corresponds to an area overlapping a top surface of the protruding pattern and the second emission area corresponds to an area overlapping a flat portion of the recess.

12. The display device of claim 10, wherein the plurality of emission areas further comprise a third emission area between the first emission area and the second emission area, the third emission area corresponding to an area overlapping an inclined portion of the protruding pattern.

13. The display device of claim 12, wherein the subpixel further comprises:
a second non-emission area surrounding the second emission area, the second non-emission area corresponding to an area overlapping the bank disposed on a flat portion of the recess.

14. The display device of claim 13, wherein the subpixel further comprises:
a fourth emission area surrounding the second non-emission area, the fourth emission area corresponding to an area overlapping an inclined portion of the recess.

15. The display device of claim 1, wherein a shape of a top surface of the bank corresponds to a shape of a top surface of the second insulating layer.

16. The display device of claim 1, wherein a top surface of the bank has a flat shape or a convex shape.

17. The display device of claim 1, wherein the subpixel further comprises:
a transistor,
wherein the first electrode and the transistor are electrically connected to each other through a contact hole that penetrates the first insulating layer and the second insulating layer.

18. The display device of claim 17, wherein the transistor comprises an active layer, a gate electrode, a source electrode, and a drain electrode,
wherein the first electrode is electrically connected to the source electrode or the drain electrode.

19. The display device of claim 1, further comprising:
an encapsulation layer over the second electrode; and
a touch sensor layer over the encapsulation layer.

20. The display device of claim 19, wherein the encapsulation layer comprises:
a first encapsulation layer comprising an inorganic insulating material;
a second encapsulation layer over the first encapsulation layer, the second encapsulation layer comprising an organic insulating material; and
a third encapsulation layer over the second encapsulation layer, the third encapsulation layer comprising an inorganic insulating material.

21. The display device of claim 19, wherein the touch sensor layer comprises:
a touch buffer layer over the encapsulation layer,
a touch electrode over the touch buffer layer, the touch electrode non-overlapping with the recess; and
a touch passivation layer over the touch electrode.

22. A display device comprising:
a substrate comprising a subpixel in an active area;
a first emission area in the subpixel;
a third emission area in the subpixel and surrounding the first emission area;
a second emission area in the subpixel and surrounding the third emission area;
a second non-emission area in the subpixel and surrounding the second emission area; and
a fourth emission area in the subpixel and surrounding the second non-emission area,
wherein a recess is in the subpixel, and a protruding pattern is within the recess.
